(19) United States
(12) Patent Application Publication
(10) Pub. No.: US 2009/0211620 A1
(43) Pub. Date: Aug. 27, 2009

(54) CONFORMAL SOLAR POWER MATERIAL

(75) Inventors: Rhonda Dibachi, Albuquerque, NM (US); Ronald Petkie, Albuquerque, NM (US); Bruce Leising, Albuqueruque, NM (US); Farzad Dibachi, Albuquerque, NM (US)

Correspondence Address: SCHWEGMAN, LUNDBERG & WOESSNER, P.A., P.O. BOX 2938, MINNEAPOLIS, MN, 55402, US

(73) Assignee: Noribachi LLC

(21) Appl. No.: 12/036,967

(22) Filed: Feb. 25, 2008

(51) Int. Cl. H01L 31/04; B29C 65/48; D03D 1/00

(52) U.S. Cl. 136/243; 156/285; 156/148

(57) ABSTRACT

A solar cell mesh includes multiple strips of flexible photovoltaic conversion cells disposed in a first direction. Multiple strips of flexible material are intertwined with the multiple strips of flexible photovoltaic material at least somewhat orthogonal to the first direction to form the mesh, such as in a fabric or net. The mesh may be applied to a curved surface of the device and encapsulated such that the mesh is conformal with the curved surface of the device.

### BACKGROUND

Solar cells are appearing in more and more products as the cost per watt decreases through high volume manufacturing processes and increasing conversion efficiency increase. Much of the research in the solar industry has focused on increasing efficiency of the modules, ordered arrays of solar cells units, in conversion of sunlight into electrical energy. Solar cells units, or solar modules on a smaller scale than conventional grid-tied modules and panels, have been applied to existing products in an ad-hoc manner wherever a benefit could be achieved from relatively lower power generation. Some of these products benefiting from solar cells include stationary applications such as landscape lighting, and construction signage. More mobile applications include flexible solar cells woven into clothing for charging portable electronics and flexible solar modules that can be unfolded to provide power in remote locations off-grid, such as recreational vehicles and camping lanterns.

### BRIEF DESCRIPTION OF THE DRAWING S

FIG. 1 is a block schematic illustration of a mid-section of interleaved flexible solar cell strip units to form a flexible woven mesh module according to an example embodiment.

FIG. 2 is a block schematic illustration of a bi-directional solar cell mesh in a net design with a fixed border according to an example embodiment.

FIG. 3 is a block schematic illustration of a string of woven mesh modules combined in series to form a panel according to an example embodiment.

FIGS. 4 and 5 illustrate a flexible solar cell having non-shaded and shaded conditions according to an example embodiment.

FIG. 6 is a current-voltage graph comparing non-shaded and shaded solar cell performance according to an example embodiment.

FIG. 7 is a perspective block diagram of a curved surface having openings for forming a vacuum fit with an encapsulated woven mesh module according to an example embodiment.

### DETAILED DESCRIPTION

In the following description, reference is made to the accompanying drawings that form a part hereof, and in which is shown by way of illustration specific embodiments which may be practiced. These embodiments are described in sufficient detail to enable those skilled in the art to practice the invention, and it is to be understood that other embodiments may be utilized and that structural, logical and electrical changes may be made without departing from the scope of the present invention. The following description of example embodiments is, therefore, not to be taken in a limited sense, and the scope of the present invention is defined by the appended claims.

A mesh including strips of solar cell unit material may be conformed to fit a curved surface. The strips of solar material may be cut from a specifically designed modular type array of solar cells formed on a flexible backing, such as Mylar or thin metal foil such as aluminum. The strips of solar material may then be weaved or tied with other flexible strips to form a mesh. The mesh may take the form of a fabric or net. The mesh may be applied to a curved surface in a conformal manner, thus allowing a product to be designed independently of the exact location of the light source, with the mesh then being applied to the finished design of the product. In some embodiments, the mesh may have solar strips and other non-solar strips woven in a manner to form a pleasing design as opposed to optimized for solar conversion efficiency. Color may be introduced into the mesh independent of the solar strip manufacturing chemistry to add further aesthetic design capability.

Products incorporating solar materials have not generally been designed from an aesthetic point of view. Some embodiments of the present invention allow such design at least because of the ability to design aesthetically pleasing meshes from both color and texture perspectives, and the ability to conform them to a large variety of surfaces.

FIG. 1 is a top view of a block diagram representation of a section of a flexible solar cell woven mesh as an example embodiment. In one embodiment, first strips of solar cell unit material 110 are oriented in a first direction. Second strips 120 of either further solar material or other material may be woven or tied into the first strips 110. The first strips 110 and second strips 120 are at least partially orthogonal to each other, and in one embodiment are substantially perpendicular to each other. In still further embodiments, different types of weaves may be used where the angle between the sets of strips is varied significantly, and in still further embodiments, more than two sets of strips may be weaved together.

In one embodiment, either material may be a warp or weft according to classic weaving terms. In one embodiment, second strips 120 may be formed of a stronger or more durable material, and may be used as a warp in a manufacturing process, with the first strips of solar cell material woven into them to form a fabric or net. In one embodiment, the second set of strips 120 may be at least partially transparent to maximize light collection by the set of solar cell strips. Pigments may be included in the strips, or in an epoxy like encapsulation of the mesh when applied to a desired surface to further increase aesthetic design flexibility and protect the solar material from ultraviolet radiation.

The warp pitch and weft pitch is given by the width of the warp and weft strips plus the spacing between the strips, respectively. That is,

Pitch of Warp=Warp strip width+Warp spacing

Pitch of Weft=Weft strip width+Weft spacing

An example of a closed mesh, which defines a fabric article, is the case where either the warp or weft spacing is about 0 mm. Cases when both pitches are greater than 0 mm results in a net weave. The mechanical properties of the mesh, namely the flexibility and conformability, and the electrical output of the solar cell strips, namely the total power generation, are inter-related through the physical and electrical attributes of the warp and weft. For example, the pitch of the warp and weft directly influence mechanical properties, namely flexibility, while the detailed nature of solar cell units in the strip design directly influence the collective voltage and currents of the mesh, namely power generation, just as in solar cell module design.

It is assumed that the intensity of light available on the surfaces of solar cell strips within the mesh will, in general, be non-uniform, as the mesh as whole may be used outdoor on curved surfaces. Non-uniform illumination in an array of solar cell units causes ‘shading effects’, which can lead to array failure when operating at high current levels. The flexible mesh described here may have an array operating at lower current levels such that the mesh or array does not suffer from the same shading heating effects as in conventional solar cell modules.

Similarly, individual solar cell units in a flexible strip may be in series and typically possess low shunt resistance and high reverse current character. These electrical properties imply that if a particular solar cell unit in a strip is completely shaded by a strip above it, the photo-generated current from other illuminated units may still pass through the shaded unit. Hence, solar cell strips with periodic dark or shaded area, as determined by the pitch in the opposite weave, will not have the effect of eliminating photo-generated current in a strip.

In one embodiment, the first strips of solar material 110 may be cut from a solar panel. The solar panel may be formed using thin film processes to produce solar cells on a flexible substrate, such as Mylar or metal foil. The resulting commercially available panels are somewhat flexible, as the solar cells may have a thickness of about 1 μm. The additional substrate may also be flexible. The strips may be cut using a knife, laser, or any other method desirable.

Optimization of mechanical and electrical performance of a mesh of strips collectively may be obtained by selecting the dimensions and solar cell diode layout within the solar cell panel consistent with the strips to be obtained from the panel. The strips may be cut and woven to form a mesh optimized for a specific product. When the strips are woven together to form a net or fabric, the resulting net or fabric may be more flexible than the original solar panel. Thinner strips may be used to further increase the flexibility of the resulting mesh. Different weaves may also be utilized to allow for a more flexible and hence conformable mesh, such as a fabric or net.

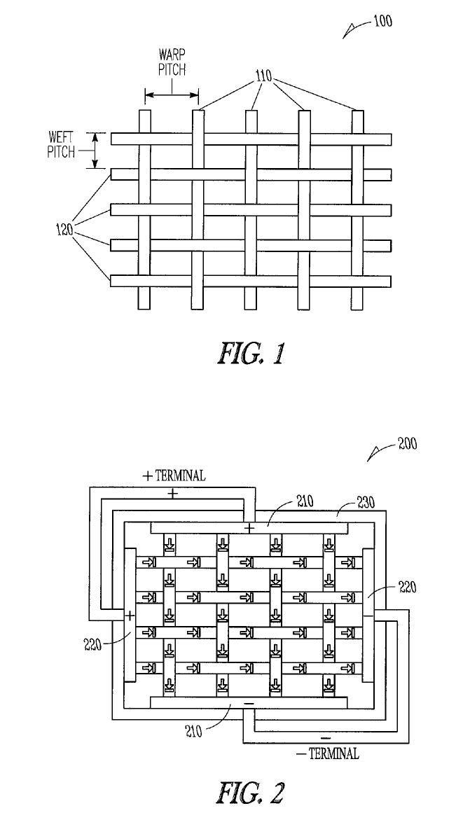

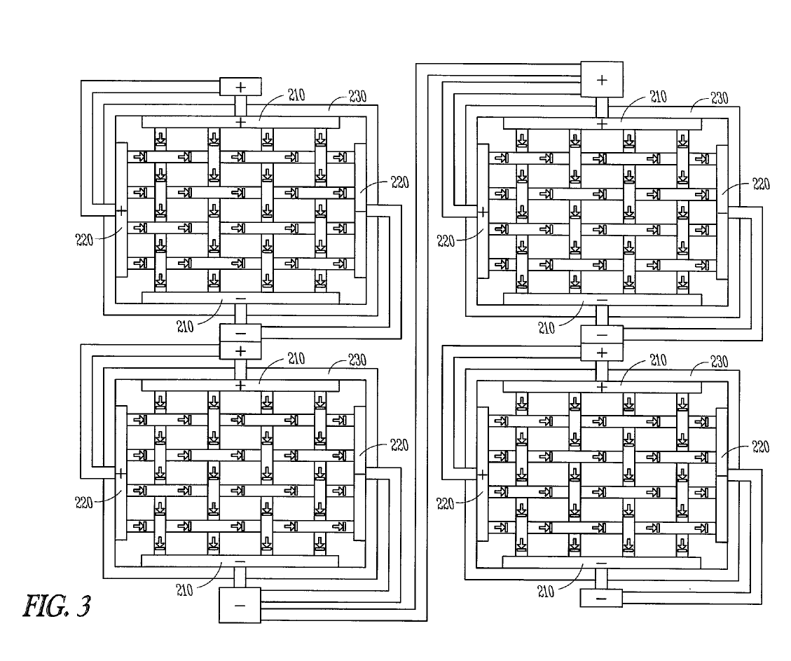

In one embodiment, the strips may be tied or otherwise coupled at selected locations to form a mesh 200 in the form of a net as illustrated in FIG. 2.

As a very basic example embodiment, the mesh 200 in FIG. 2 includes woven solar cell strips in a bi-directional design with a substantially matched number of solar cell diodes in each strip. These strips can be cut from commercially available Mylar substrate solar cell diode arrays. Each strip consists of diodes connected in series as shown to essentially match the pitch of the warp and weft in this case of a net weave. All strips are designed to have substantially the same operational performance as determined by the solar cell manufacturing process and to minimize performance mismatching effects in the collection of photo-generated power. In one embodiment, the strips may be connected in parallel for each set of strips within the warp and weft. Terminals may be electrically coupled to provide an electrical output suitable for a designed product.

As a specific example of a fabric design in FIG. 2, where the spacing is approximately 0 mm and again made from available flexible solar cell panels, the overall designed could be about 4.5 by 2.0 inches for a rectangular shaped design. Four strips having similar electrical characteristics in each direction, with each strip width of 0.5 inches wide by 4.5 inches long, with an allowance of 0.5 inches in the length for the conductive strip terminals. Each strip in one embodiment has 5 solar cell diodes in series. Typical maximum power operating voltages in AM1.5 illumination for a single diode is about 0.6 volts, so the output voltage for a strip of 5 solar cell diodes in series is 3.0 volts. The operating current for the same condition is typically 0.011 amps for each strip, which yields an output power of 0.033 watts for each strip in the fabric. Since there are a substantially equal number of diodes in series in each strip, under ideal conditions, the output voltage will be the same for each strip, and be equal for each set of warp and weft strips. The warp and weft strips can be connected in parallel to provide the final output power.

In a further embodiment, each strip is capable of generating 0.011 amps under normal operating conditions, and there are 8 strips in all, resulting in a potential operating output current could of 0.088 amps at 3.0 volts. Thus, the potential power is 0.26 watts without consideration of shadowing effects from the interleaved strips. In still further embodiments, mesh 200 may be considered an example of a basic mesh module, where modules may be combined for additional power output.

The operational power output of a mesh, with interleaved shading effects, is estimated by considering the area shaded. For one example embodiment, where there are an equal number of strips in each the warp and weft and all strips have approximately the same width, the total shaded in the design is given by 8×0.5″×0.5″=2 in². The total active area of the solar cell strips is given by is given by 4″×2″=8 in². Assuming the maximum available power is roughly given by the illuminated area, and the illuminated area is reduced by 25% from interleaved shading effects, then the operational power level is estimated to be 75% of the normal operational power level. The power output for this design with the shading effect is then about 0.19 watts.

FIG. 3 illustrates the cumulative effects of adding the basic module design mesh 200 in FIG. 2, analogous to panel design in the larger solar cell module and panel arrays. The interleaved mesh 200 of FIG. 2 defines a module and can be used to make a solar cell panel capable of providing 12 volts as output for re-charging batteries. More specifically, by stringing four mesh 200 module units in series to increase the voltage to 12 volts, the available power is four times that of the unit design, which is estimated to be 0.78 watts with shading effects considered. Similarly, the maximum available current may be increased by adding another 1×4 module in parallel, increasing the maximum power achievable by an additional 0.78 watts per added module. In addition, the width of the strips may be selected to provide a desired amount of current flow for each strip. Sets of strips having desired voltages and current may be coupled in series or in parallel to provide desired voltage and current characteristics. Insulation from the original solar panel used to form the strips may be removed at desired positions, such as ends of strips, and electrical connections made at such positions.

Typical lengths for the strips of solar materials range from 15 cm to 90 cm. Lengths of at least up to 45 m or longer may be used in further embodiments. In some embodiments, a strip may contain several cells that are coupled in series to provide a desired voltage. The width of a strip is proportional to the amount of current that can be provided. The width of the strip may be a trade off between several factors, including aesthetic factors, conformal factors, and current factors. Typical widths of the solar strips range from less than 0.5 cm to about 3 cm. Wider widths may be used if desired, such as for use in covering very large surfaces, which may be viewed from a distance. Aesthetic design desires may lead to the use of a larger width for viewing at a distance. The use of strips of solar material in a mesh provides great flexibility to accomplish aesthetic design desires.

A further embodiment involves the electrical properties of the solar cells themselves. Normally, a by-pass diode is required in modules to accommodate shading effects and prevent overheating and possible destruction. Such a by-pass diode routed current around the shaded solar cell. Additionally, to maximize the efficiency in solar cells, the cells are typically designed to have a high shunt resistance. In thin film flexible solar cells used in applications where shading may occur during a significant portion of the operational lifetime, a lower shunt resistance is advantageous. A solar cell with relatively low shunt resistance will allow current to pass through it even when 100% shaded, as it then operates as a series resistor, rather than preventing photo-generated current from flowing altogether, which could be the case for an ideal solar cell diode.

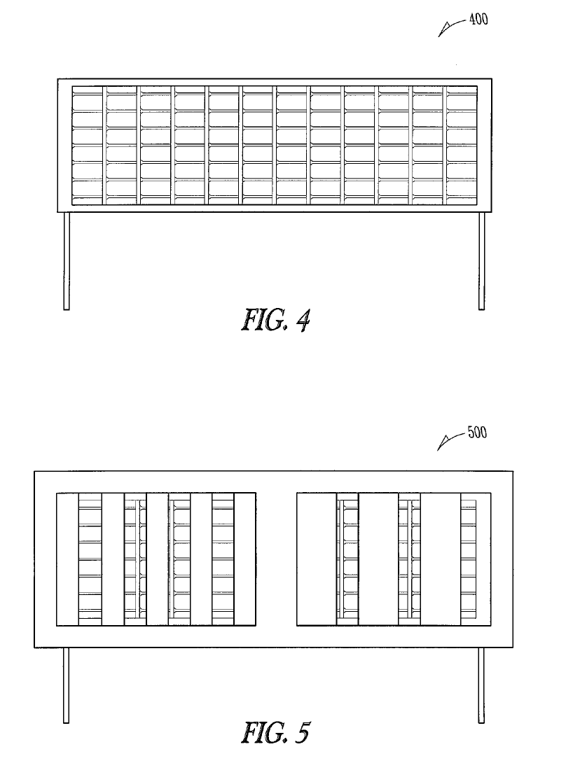

FIGS. 4 and 5 illustrate a flexible solar cell having non-shaded and shaded conditions according to an example embodiment. Opaque cardboard was used as the shading material in one embodiment for testing purposes. Approximately 50% of the active cell's area is shaded. In commercial embodiments, the weave patterns may create similar shading, while in other embodiments, materials may be transparent, resulting in minimal shading effects.

The graph in FIG. 6 illustrates current—voltage characteristic of a commercially available thin film flexible solar module under a halogen lamp in close proximity. The module is shown in FIG. 4 at 400 (non-shaded) and FIG. 5 at 500 (shaded). It should be noted that even though some of the cells are partially or fully shaded, photo-generated current is still passing through the solar cell module. In conventional cells, it is possible that current would be stopped altogether, since they are designed to have much higher shunt resistance, resulting in very low current under shaded conditions. Hence, a low shunt resistance effectively replaces the function of a by-pass diode. The result for low shunt resistance solar cells is that even under low levels of illumination or when the cells are interwoven and partially shade one another, photo-generated current can still be produced.

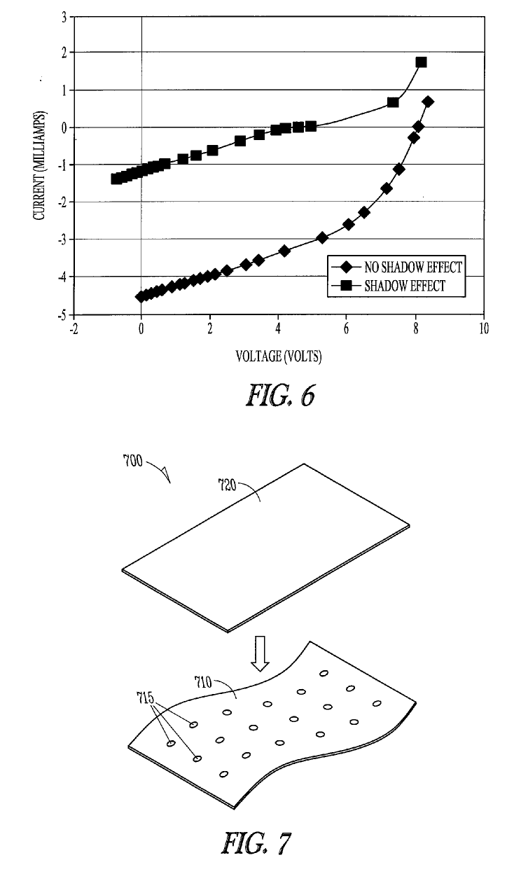

FIG. 7 is a perspective block diagram 700 of a curved surface 710 having openings 715 for forming a vacuum fit with an encapsulated woven mesh module 720 according to an example embodiment. In one embodiment, the curved surface 710 may be any type of product on which it is desireable to add solar material. Products such as appliances, roofs, automobiles, outdoor lighting, etc., may have containers or exteriors that have holes 715 allowing for the creation of a vacuum between the curved surface 710 and the encapsulated module 720. In one example embodiment, a perforated substrate is provided for placing and bonding of flexible solar cells, by which a partial vacuum is created on the side opposite a mounting side for holding the cells in place during the bonding of the solar cells by an adhesive. The holes should be sized and spaced to provide for desired conformance of the solar cells to the product. In one embodiment the solar cells are an encapsulated woven mesh module. The encapsulation provides sufficient air flow resistance to allow conformance of the module to the curved surface of the product and adhesion thereto via a separate adhesive, or heat that partially melts the encapsulating material causing it to adhere to the surface.

The Abstract is provided to comply with 37 C.F.R. §1.72(b) to allow the reader to quickly ascertain the nature and gist of the technical disclosure. The Abstract is submitted with the understanding that it will not be used to interpret or limit the scope or meaning of the claims.

1. A method of adding solar material to a device, the method comprising:
forming strips of flexible solar material;
creating a mesh from the strips of flexible solar material wherein the strips are electrically coupled to each other;
applying the mesh to a curved surface of the device; and
encapsulating the mesh such that it is conformal with the curved surface of the device.

2. The method of claim 1 wherein the strips of flexible solar material are cut from a panel of solar material.

3. The method of claim 1 wherein the strips have segments of solar cells that are electrically coupled in series to obtain a desired voltage for the strips.

4. The method of claim 3 wherein the strips have a width adapted to provide a desired amount of current.

5. The method of claim 1 wherein the strips are weaved to form a fabric.

6. The method of claim 1 wherein the mesh is tied to form a net.

7. The method of claim 1 wherein the strips are weaved with non-solar transparent strips.

8. The method of claim 1 wherein the encapsulated mesh is tinted to a desired color independent of chemistry of the strips.

9. The method of claim 1 wherein the mesh is at least partially encapsulated and applied to the curved surface using a vacuum.

10. A solar energy mesh comprising:
multiple strips of flexible solar material disposed in a first direction; and
multiple strips of flexible material intertwined with the multiple strips of flexible material at least partially orthogonal to the first direction.

11. The solar energy mesh of claim 10 wherein the strips of flexible material comprise strips of flexible solar material.

12. The solar energy mesh of claim 10 and further comprising electrical connections to the strips of flexible solar material arranged to provide a desired voltage and current.

13. The solar energy mesh of claim 10 wherein the multiple strips of flexible solar material have widths adapted to provide a desired current.

14. The solar energy mesh of claim 10 wherein the strips are adapted to provide a conformal solar energy mesh.

15. A solar device comprising:
a first solar mesh module having multiple strips of flexible solar material disposed in a first direction, wherein each strip is electrically connected to provide a desired voltage and current;
multiple strips of flexible material intertwined with the multiple strips of flexible material in each module at least somewhat orthogonal to the first direction; and
the first solar mesh module having inter module electrical connectors for connecting to one or more further solar mesh modules to obtain a solar device having desired electrical properties.

16. The solar device of claim 15 wherein the inter module connectors operate to electrically couple solar mesh modules in series to obtain a desired voltage.

17. The solar device of claim 16 wherein each strip of flexible solar material in a module contains approximately the same number of photo diodes coupled in series.

18. The solar device of claim 16 wherein the intertwined strips also comprise photo diodes coupled in series.

19. The solar device of claim 18 wherein the intertwined strips and the multiple strips of flexible solar material disposed in a first direction are coupled in parallel.

20. The solar device of claim 16 wherein the inter module connectors also operate to selectively couple modules in parallel to obtain a desired current.

21. A perforated substrate for placing and bonding of flexible solar cells, by which a partial vacuum is created on a side opposite a mounting side for holding the flexible solar cells in place during the bonding of the solar cells by an adhesive.

22. A flexible solar cell having low shunt resistance so that current may pass through the cell when shaded.
